(19) United States
(12) Patent Application Publication
(10) Pub. No.: US 2025/0215206 A1
(43) Pub. Date: Jul. 3, 2025

(54) RESIN COMPOSITION FOR FORMING PHASE-SEPARATED STRUCTURE AND METHOD FOR PRODUCING STRUCTURE HAVING PHASE-SEPARATED STRUCTURE

(71) Applicant: TOKYO OHKA KOGYO CO., LTD., Kawasaki-shi (JP)

(72) Inventors: Junichi TSUCHIYA, Kawasaki-shi (JP); Ken MIYAGI, Kawasaki-shi (JP); Takehiro SESHIMO, Kawasaki-shi (JP)

(21) Appl. No.: 18/989,785

(22) Filed: Dec. 20, 2024

(30) Foreign Application Priority Data
Dec. 27, 2023 (JP) 2023-220918

(51) Int. Cl. C08L 53/00; C08F 212/08; C08F 220/14; C08F 220/38

(52) U.S. Cl. CPC C08L 53/00; C08F 212/08; C08F 220/14; C08F 220/38; C08L 2205/025

(57) ABSTRACT

A resin composition for forming a phase-separated structure. The resin composition includes a first block copolymer having a first-a block and a first-b block; and a second block copolymer having a second-a block and a second-b block, in which the first-a block and the second-a block are each independently include a polymer having a repeating structure of a constituent unit represented by formula (b1), the second-b block includes a polymer having a repeating structure of a constituent unit represented by formula (b2b), the second block copolymer has a number-average molecular weight of 40000 or less, and the first block copolymer satisfies a predetermined requirement

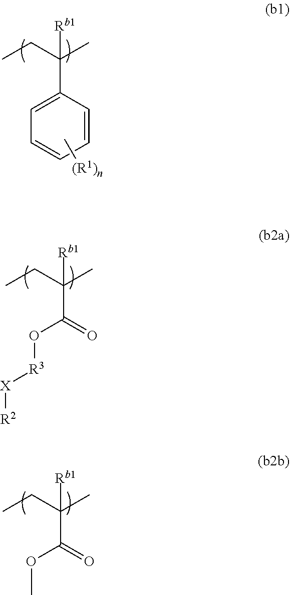

This application claims priority to Japanese Patent Application No. 2023-220918, filed Dec. 27, 2023, the entire content of which is incorporated herein by reference.

### BACKGROUND OF THE INVENTION

### Field of the Invention

The present invention relates to a resin composition for forming a phase-separated structure and a method for producing a structure having a phase-separated structure.

### Related Art

In recent years, following further miniaturization of a large-scale integrated circuit (LSI), a technique for processing a finer structure has been demanded. In response to this demand, a technique has been developed to form finer patterns by utilizing a phase-separated structure formed by directed self-assembly of block copolymers in which mutually incompatible blocks are bonded to each other (see Patent Document 1, for example).

The block copolymers separate (phase-separate) into micro-regions due to repulsion between the mutually incompatible blocks, and then are subjected to heat treatment, etc. to form a structure having a regular periodic structure. Specific examples of the periodic structure include a cylinder (columnar), lamella (plate-like) and sphere (spherical).

To use this phase-separated structure of block copolymers, it is essential that the self-assembled nanostructures formed by micro-phase separation be formed only in specific regions and be arranged in the desired direction. To control the position and orientation of these nanostructures, processes such as graphene epitaxy, which controls phase separation patterns by guiding patterns, and chemical epitaxy, which controls phase separation patterns by differences in the chemical state of the substrate, have been proposed (see, for example, Non-Patent Document 1).

The block copolymer forms a structure having a regular periodic structure by phase separation. The term “structural period” means a period of a phase structure observed when a structure having a phase-separated structure is formed and refers to a sum of lengths of phases incompatible with each other. When a phase-separated structure forms a cylinder structure perpendicular to a surface of a substrate, the structural period (L₀) is the distance between centers (pitch) of the two adjacent cylinder structures.

It is known that the structural period (L₀) is determined by inherent polymerization properties such as the degree of polymerization N and the Flory-Huggins interaction parameter χ. That is, the larger the product of χ and N “χ·N”, the greater the mutual repulsion between the different blocks in the block copolymer. Therefore, in the case of χ·N>10.5 (hereinafter, referred to as “intensity separation limit”), repulsion between different kinds of blocks in the block copolymer is large, leading to a stronger tendency to induce phase separation. Accordingly, at the intensity separation limit, the structural period is approximately N^{2/3}·χ^{1/6}, and the relationship expressed in the following formula (1) is satisfied. That is, the structural period is proportional to the degree of polymerization N, which correlates with the molecular weight and the molecular weight ratio between different blocks.

L₀∝a·N^{2/3}· ^{1/6} (1)

[In the formula, L₀ denotes a structural period;
a is a parameter indicating a size of a monomer;
N denotes a degree of polymerization; and
χ is an interaction parameter in which a higher value means higher phase separation performance.]

Accordingly, the structural period (L₀) can be controlled by adjusting the composition and total molecular weight of block copolymers. Thus, in order to form a structure with a smaller L₀ by using the phase-separated structure formed by the directed self-assembly of the block copolymer, a method of reducing a molecular weight of the block copolymer has been considered. However, simply reducing the molecular weight of the block copolymer may cause a problem of decrease in the degree of polymerization (N) to fail the phase separation. Accordingly, required is a material having a large interaction parameter (χ) (high-χ material) for phase separation even with the reduced molecular weight of the block copolymer, but such a high-χ material typically has a low phase separation rate, and thus a condition capable of performing the phase separation is limited, which lacks practicality.

For example, Patent Literature 2 proposes, as a high-χ material solving such a disadvantage, a block copolymer having: a styrene block; and a block composed of a random copolymer of 2-hydroxy-3-(2,2,2-trifluoroethylsulfanyl) propyl methacrylate and methyl methacrylate, as a block copolymer having χ larger than that of the block copolymer having the styrene block and the methyl methacrylate block, and Patent Literature 2 describes that phase separation can be made under the conventional condition.
Patent Document 1: Japanese Unexamined Patent Application, Publication No. 2008-36491
Patent Document 2: Japanese Unexamined Patent Application, Publication No. 2022-20519
Non-Patent Document 1: Proc. SPIE 7637, Alternative Lithographic Technologies II, 76370G (1 Apr. 2010)

### SUMMARY OF THE INVENTION

Although Patent Literature 2 describes that phase separation can be made under the conventional condition as noted above, it has been required that the phase separation rate is further increased to reduce Fingerprint Edge Roughness (FER) and to broaden Grain for a purpose of further improving the practicality. The phase separation into a lamella structure without forming a guide pattern yields a phase-separated structure with a random fingerprint pattern, and an index of roughness of such a fingerprint pattern is FER. It is known that use of a material to yield a phase-separated structure having low FER can reduce roughness during formation of a DSA pattern. The phase separation into a cylinder structure without forming a guide pattern forms a pattern in which cylinder structures are oriented at positions corresponding to a plane-viewed hexagonal close-packed structure, and a region (lump) where same orientation patterns continue is Grain. That is, a certain Grain and a Grain adjacent thereto have different orientation patterns of the cylinder structure. It is known that use of a material to yield a phase-separated structure having a large Grain can reduce error during formation of a DSA pattern.

The present invention has been made in view of the above circumstances, with the object of providing a resin composition for forming a phase-separated structure that can form a phase-separated structure having reduced pattern roughness or pattern error, and a method for producing a structure having a phase-separated structure using this resin composition.

As a result of extensive studies by the present inventors to solve the above problem, the present invention has been completed based on findings that the above object can be solved by using a predetermined second block copolymer in addition to a predetermined first block copolymer, which is a high-χ material. Specifically, the present invention provides the following aspects.
[1] A resin composition for forming a phase-separated structure, the resin composition including: a first block copolymer; and a second block copolymer, in which
   the first block copolymer has a first-a block and a first-b block,
   the second block copolymer has a second-a block and a second-b block,
   the first-a block and the second-a block are each independently constituted by a polymer having a repeating structure of a constituent unit represented by formula (b1),
   the second-b block is constituted by a polymer having a repeating structure of a constituent unit represented by formula (b2b),
   the second block copolymer has a number-average molecular weight of 40,000 or less in terms of standard polystyrene as determined by gel permeation chromatography (GPC) measurement,
   the first block copolymer satisfies any one of (1) or (2):
   (1) the first-b block is constituted by a random copolymer having a structure in which a constituent unit represented by formula (b2a) and the constituent unit represented by the following formula (b2b) are randomly arranged,
   (2) in the first-a block, n in the following formula (b1) is an integer between 1 and 5 inclusive, and
   the first-b block is constituted by a polymer having a repeating structure of the constituent unit represented by the following formula (b2b):

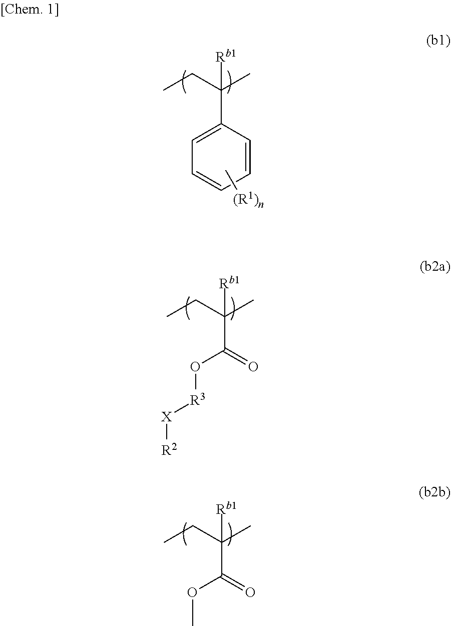

wherein, in the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality of R¹ may be same as or different from each other,
in the formula (b2a), X is a sulfur atom or an oxygen atom, R³ is an alkylene group optionally having a hydroxy group, and R² is a hydrogen atom or a monovalent organic group, and
in the formula (b2a) and the formula (b2b), R^{b2} is each independently a hydrogen atom, an alkyl group having 1 or more and 5 or less carbon atoms, or a halogenated alkyl group having 1 or more and 5 or less carbon atoms, and a plurality of R^{b2} may be same as or different from each other.
[2] The resin composition for forming a phase-separated structure according to [1], in which R² in the formula (b2a) is a hydrogen atom, an acyl group, a thioacyl group, an alkenyl group, or an alkyl group optionally having a silyl group, a fluorine atom, a carboxy group, an amino group, a hydroxy group, or a phosphoric acid group.
[3] The resin composition for forming a phase-separated structure according to [1] or [2], in which a proportion of a mass of the first block copolymer to a sum of the mass of the first block copolymer and a mass of the second block copolymer is 30 mass % or more and 95 mass % or less.
[4] The resin composition for forming a phase-separated structure according to any one of [1] to [3], in which
   a proportion of a number of moles of a constituent unit of the first-a block to a sum of the number of moles of the constituent unit of the first-a block and a number of moles of the constituent unit of the first-b block is 20 mol % or more and 80 mol % or less, and
   a proportion of a number of moles of a constituent unit of the second-a block to a sum of the number of moles of the constituent unit of the second-a block and a number of moles of the constituent unit of the second-b block is 20 mol % or more and 80 mol % or less.
[5] The resin composition for forming a phase-separated structure according to any one of [1] to [4], in which, when the first block copolymer satisfies the (1), a ratio of a number of moles of the constituent unit represented by the formula (b2a) to a sum of the number of moles of the constituent unit represented by the formula (b2a) and a number of moles of the constituent unit represented by the formula (b2b) in the first-b block is 0.90 or less.
[6] A method for producing a structure having a phase-separated structure, the method comprising applying the resin composition for forming a phase-separated structure according to any one of [1] to [5] on a support to form a layer containing a block copolymer; and
   phase separating the layer containing the block copolymer.

According to the present invention, a resin composition for forming a phase-separated structure that can form a phase-separated structure having reduced pattern roughness or pattern error, and a method for producing a structure having a phase-separated structure using this resin composition can be provided.

### BRIEF DESCRIPTION OF THE DRAWINGS

FIG. 1 is a schematic process diagram illustrating an exemplary embodiment of a method for producing a structure having a phase-separated structure;

FIG. 2 is a diagram illustrating an exemplary embodiment of an optional process;

FIG. 3 is a diagram showing an SEM image on a substrate surface in Example 3;

FIG. 4 is a diagram showing an SEM image on a substrate surface in Comparative Example 1;

FIG. 5 is a diagram showing an SEM image on a substrate surface in Example 12; and

FIG. 6 is a diagram showing an SEM image on a substrate surface in Comparative Example 2.

### DETAILED DESCRIPTION OF THE INVENTION

Although embodiments of the present invention will be described below in detail, the present invention is not limited to the embodiments below in any way and can be implemented with modifications as appropriate within the scope of the object of the present invention.

As used herein, the term “aliphatic” is defined as a concept relative to aromatic and means a group, a compound, etc. having no aromaticity. Unless otherwise specified, the term “alkyl group” means a linear- or branched-chain monovalent saturated hydrocarbon group. The same applies to an alkyl group in an alkoxy group. Unless otherwise specified, the term “cycloalkyl group” means a monocyclic cyclic saturated hydrocarbon group. Unless otherwise specified, the term “alkylene group” means a linear- or branched-chain divalent saturated hydrocarbon group. The term “halogenated alkyl group” means a group in which a portion or all of hydrogen atoms in an alkyl group is substituted with a halogen atom. Examples of the halogen atom include a fluorine atom, a chlorine atom, a bromine atom, or an iodine atom. The term “fluorinated alkyl group” or “fluorinated alkylene group” means a group in which a portion or all of the hydrogen atoms in an alkyl group or an alkylene group is substituted with a fluorine atom. The term “constituent unit” means a monomer unit (monomeric unit) constituting a polymer compound (resin, polymer, or copolymer). The phrase “constituent unit derived from” means a constituent unit derived from the cleavage of an ethylenic double bond or a cyclic ether. The phrase “optionally having a substituent” includes both of a case where a hydrogen atom (—H) is substituted with a monovalent group and a case where a methylene group (—CH₂—) is substituted with a divalent group. The term “exposure” means general irradiation with radiation. Unless otherwise specified, the term “α-position (carbon atom at an α-position)” means a carbon atom to which a side chain of a block copolymer is bonded. The term “carbon atom at an α-position” of a methyl methacrylate unit means a carbon atom to which a carbonyl group in methacrylic acid is bonded. The term “carbon atom at an α-position” of a styrene unit means a carbon atom to which a benzene ring is bonded. Unless otherwise specified, the term “number-average molecular weight” (Mn) and “weight-average molecular weight” (Mw) mean a number-average molecular weight and a weight-average molecular weight in terms of standard polystyrene as determined by gel permeation chromatography (GPC) measurement (solvent: tetrahydrofuran (THF), flow amount (sample injection amount): 20 μL, column: TOSOH TSK Gel Super HM-N (three columns in series), column temperature: 40° C., flow rate 0.6 mL/min, detector: differential refractometer (RI)). When a value of Mn or Mw is followed by a unit (gmol⁻¹), the value represents a molar mass. Herein, an asymmetric carbon may exist depending on the structure represented by a chemical formula, and thus an enantiomer or a diastereomer may exist. In such cases, one formula is used for representing these isomers. These isomers may be used alone or used as a mixture.

Resin Composition for Forming Phase-Separated Structure A resin composition for forming a phase-separated structure comprises a first block copolymer and a second block copolymer. The first block copolymer has a first-a block and a first-b block, and the second block copolymer has a second-a block and a second-b block. The first-a block and the second-a block are each independently constituted by a polymer having a repeating structure of a constituent unit represented by the following formula (b1), and the second-b block is constituted by a polymer having a repeating structure of a constituent unit represented by the following formula (b2b). The second block copolymer has a number-average molecular weight of 40000 or less in terms of standard polystyrene as determined by gel permeation chromatography (GPC) measurement. The first block copolymer satisfies any one of the following (1a) or the following (2).
(1) The first-b block is constituted by a random copolymer having a structure in which a constituent unit represented by the following formula (b2a) and the constituent unit represented by the following formula (b2b) are randomly arranged.
(2) In the first-a block, n in the following formula (b1) is an integer between 1 and 5 inclusive, and the first-b block is constituted by a polymer having a repeating structure of the constituent unit represented by the following formula (b2b).

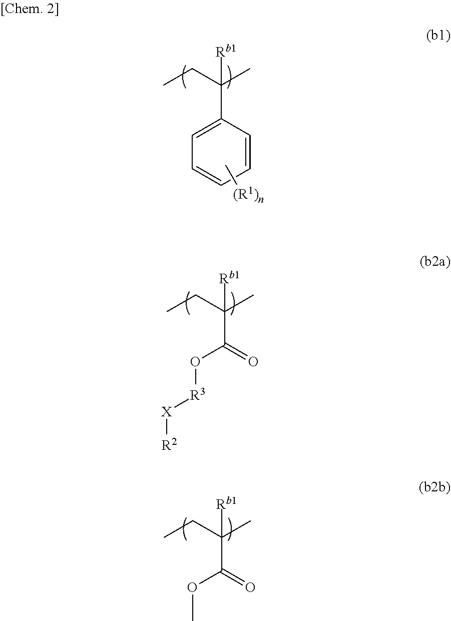

(In the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality of R¹ may be the same as or different from each other,
in the formula (b2a), X is a sulfur atom or an oxygen atom, R³ is an alkylene group optionally having a hydroxy group, and R² is a hydrogen atom or a monovalent organic group, and
in the formula (b2a) and the formula (b2b), R^{b2} is each independently a hydrogen atom, an alkyl group having 1 or more and 5 or less carbon atoms, or a halogenated alkyl group having 1 or more and 5 or less carbon atoms, and a plurality of R^{b2} may be the same as or different from each other.)

Since satisfying any one of the (1) or the (2), the first block copolymer has a large interaction parameter, and can form a structure having a smaller L₀. The second block copolymer has a number-average molecular weight of 40000 or less, and due to the relationship of the product χ·N of the interaction parameter and the degree of polymerization, the second block copolymer hardly induces phase separation. The present inventors have found that use of such a second block copolymer to hardly induce phase separation, in addition to the first block copolymer having a large interaction parameter, can increase the phase-separation rate to reduce pattern roughness or pattern error.

### <First Block Copolymer>

The first block copolymer has a first-a block and a first-b block. The first-a block is constituted by a polymer having a repeating structure of a constituent unit represented by the formula (b1), and satisfies any one of the (1) or the (2).

### [First-a Block]

The first-a block is constituted by a polymer having a repeating structure of a constituent unit represented by the following formula (b1) (hereinafter, which may be referred to as “constituent unit (b1)”).

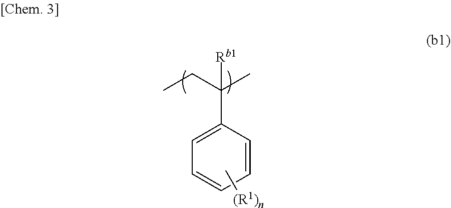

(In the formula (b1), R¹ is an alkyl group optionally having an oxygen atom or a silicon atom, n is an integer between 0 and 5 inclusive, and when n is an integer of 2 or more, a plurality of R¹ may be the same as or different from each other, and R^{b1} is a hydrogen atom or a methyl group.)

The alkyl group optionally having an oxygen atom and/or a silicon atom is preferably an alkyl group optionally interrupted by an oxygen atom and optionally substituted with an alkylsilyl group. Specific examples thereof include an alkyl group, an alkylsilyl group, an alkylsilylalkyl group, an alkylsilyloxy group, an alkylsilyloxyalkyl group, and an alkoxy group.

Examples of the alkyl group include a methyl group, an ethyl group, a n-propyl group, an isopropyl group, a n-butyl group, a sec-butyl group, and a tert-butyl group.

The alkylsilyl group is preferably a trialkylsilyl group. Specific examples thereof include a trimethylsilyl group. The alkylsilylalkyl group is preferably a trialkylsilylalkyl group. Specific examples thereof include a trimethylsilylmethyl group, a 2-trimethylsilylethyl group, and a 3-trimethylsilyl-n-propyl group. The alkylsilyloxy group is preferably a trialkylsilyloxy group. Specific examples thereof include a trimethylsilyloxy group. The alkylsilyloxyalkyl group is preferably a trialkylsilyloxyalkyl group. Specific examples thereof include a trimethylsilyloxymethyl group, a 2-trimethylsilyloxyethyl group, and a 3-trimethylsilyloxy-n-propyl group. Examples of the alkoxy group include a methoxy group, an ethoxy group, a n-propoxy group, an isopropoxy group, a n-butoxy group, a sec-butoxy group, and a tert-butoxy group.

The number of carbon atoms of an entirety of the alkyl group optionally interrupted by an oxygen atom and optionally substituted with the alkylsilyl group is preferably 1 or more and 10 or less, more preferably 1 or more and 5 or less, further preferably 1 or more and 3 or less, and particularly preferably 1 or 2.

In the case of the (1), n is preferably an integer between 0 and 3 inclusive, more preferably 0 or 1, and further preferably 0. In the case of the (2), n is an integer between 1 and 5 inclusive, preferably an integer between 1 and 3 inclusive, and more preferably 1.

### [First-b Block]

In the case of the (1), the first-b block is constituted by a random copolymer having a structure in which a constituent unit represented by the following formula (b2a) (hereinafter, which may be referred to as “constituent unit (b2a)”) and the constituent unit represented by the following formula (b2b) (hereinafter, which may be referred to as “constituent unit (b2b)”) are randomly arranged. In the case of the (2), the first-b bock is constituted by a polymer composed of a structure of the constituent unit represented by the formula (b2b).

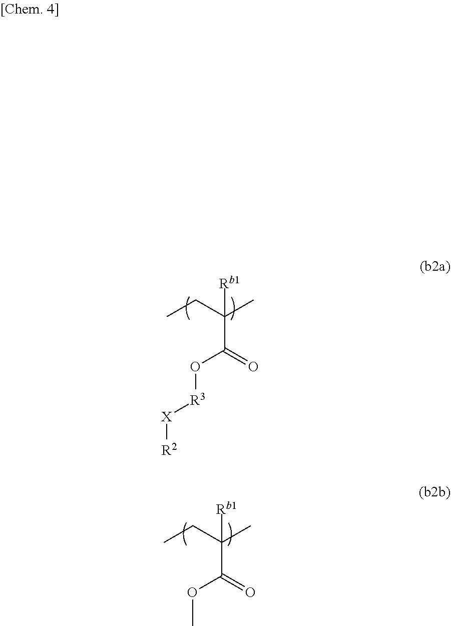

(In the formula (b2a), X is a sulfur atom or an oxygen atom, R³ is an alkylene group optionally having a hydroxy group, and R² is a hydrogen atom or a monovalent organic group, and
in the formula (b2a) and the formula (b2b), R^{b2} is each independently a hydrogen atom, an alkyl group having 1 or more and 5 or less carbon atoms, or a halogenated alkyl group having 1 or more and 5 or less carbon atoms, and a plurality of R^{b2} may be the same as or different from each other.)
   (Constituent Unit (b2a))

The number of carbon atoms of the monovalent organic group in R² is preferably 1 or more and 30 or less, more preferably 1 or more and 20 or less, further preferably 1 or more and 10 or less, and particularly preferably 1 or more and 5 or less.

The monovalent organic group in R² is preferably an acyl group, a thioacyl group, an alkenyl group, or an alkyl group optionally having a silyl group, a fluorine atom, a carboxy group, an amino group, a hydroxy group, or a phosphoric acid group, and more preferably an acyl group or an alkyl group optionally having a fluorine atom.

The number of carbon atoms of the acyl group in R² is preferably 1 or more and 10 or less, more preferably 1 or more and 5 or less, and further preferably 1 or more and 3 or less. Examples of the acyl group in R² include a formyl group, an acetyl group, and a propionyl group. Among these, an acetyl group is preferable. The number of carbon atoms of the thioacyl group in R² is preferably 1 or more and 10 or less, more preferably 1 or more and 5 or less, and further preferably 1 or more and 3 or less. Examples of the thioacyl group in R² include a thioformyl group, a thioacetyl group, and a thiopropionyl group. Among these, a thioacetyl group is preferable. The number of carbon atoms of the alkenyl group in R² is preferably 2 or more and 10 or less, and more preferably 3 or more and 5 or less. Examples of the alkenyl group in R² include an allyl group and an isopropenyl group. Among these, an allyl group is preferable.

The number of carbon atoms of the alkyl group in R² is preferably 1 or more and 20 or less, more preferably 1 or more and 20 or less, further preferably 1 or more and 10 or less, and particularly preferably 1 or more and 5 or less. The alkyl group in R² is preferably linear. Examples of the alkyl group in R² include a methyl group, an ethyl group, a n-propyl group, an isopropyl group, a n-butyl group, an isobutyl group, a sec-butyl group, a tert-butyl group, a n-pentyl group, a n-hexyl group, a n-heptyl, a n-octyl, a n-nonyl, and a n-decyl. Among these, a methyl group, an ethyl group, a n-propyl group, a n-butyl group, a n-pentyl group, a n-hexyl group, a n-heptyl, and a n-octyl are preferable, and a methyl group, an ethyl group, and a n-propyl group are more preferable.

When the alkyl group in R² has a silyl group, a fluorine atom, a carboxy group, an amino group, a hydroxy group, or a phosphoric acid group, the silyl group etc. are a substituent substituting a hydrogen atom in the alkyl group. The number of the substituted hydrogen atoms is preferably 1 or more and 5 or less, and more preferably 1 or more and 3 or less. Examples of the silyl group that the alkyl group in R² optionally has include alkylsilyl groups such as a monoalkylsilyl group, a dialkylsilyl group, and a trialkylsilyl group. Among these, a trialkylsilyl group is preferable. The number of carbon atoms of the alkyl group in the alkylsilyl group is preferably 1 or more and 5 or less, and more preferably 1 or more and 3 or less. Examples of the alkyl group in the alkylsilyl group include a methyl group, an ethyl group, a n-propyl group, an isopropyl group, a n-butyl group, an isobutyl group, a sec-butyl group, a tert-butyl group, and a n-pentyl group. Among these, a methyl group and an ethyl group are preferable, and a methyl group is more preferable.

The number of carbon atoms of the alkylene group in R³ is preferably 1 or more, and more preferably 3 or more. The number of carbon atoms of the alkylene group is preferably 10 or less, and from the viewpoint of phase-separation ability, more preferably 8 or less, further preferably 5 or less, and particularly preferably 4 or less. The number of carbon atoms of the alkylene group is most preferably 3. The alkylene group in R³ is preferably linear.

When the alkylene group in R³ has a hydroxy group, the number of the hydroxy groups is preferably 1 or more and 3 or less, more preferably 1 or 2, and further preferably 1.

In the formula (b2a), examples of the alkyl group as R^{b2} having 1 or more and 5 or less carbon atoms include a methyl group, an ethyl group, a propyl group, an isopropyl group, a n-butyl group, a sec-butyl group, a tert-butyl group, a n-pentyl group, a neopentyl group, an isopentyl group, a sec-pentyl group, a 3-pentyl group, and a tert-pentyl group. The halogenated alkyl group having 1 or more and 5 or less carbon atoms is a group in which a portion or all of hydrogen atoms in the alkyl group having 1 or more and 5 or less carbon atoms are substituted with a halogen atom. The halogen atom is particularly preferably a fluorine atom.

In the formula (b2a), R^{b2} is preferably a hydrogen atom or an alkyl group having 1 or more and 5 or less carbon atoms, and in terms of industrial availability, more preferably a hydrogen atom or a methyl group, and further preferably a methyl group.

The constituent unit (b2a) is preferably a constituent unit represented by the following formula (b2a-1).

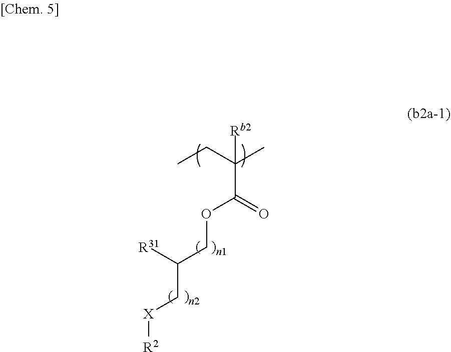

(In the formula (b2a-1), R³¹ is a hydrogen atom or a hydroxy group, n1 is an integer between 1 and 5 inclusive, n2 is an integer between 0 and 5 inclusive, and X, R², and R^{b2} are the same as X, R², and R^{b2} in the formula (b2a), respectively.)
n1 is preferably an integer between 1 and 3 inclusive, more preferably 1 or 2, and further preferably 1. n2 is preferably an integer between 0 and 3 inclusive, more preferably 0 or 1, and further preferably 1.
   (Constituent Unit (b2b))

R^{b2} in the formula (b2b) is the same as R^{b2} in the formula (b2a).

When the first block copolymer satisfies the (1), a ratio of the number of moles of the constituent unit represented by the formula (b2a) to a sum of the number of moles of the constituent unit represented by the formula (b2a) and the number of moles of the constituent unit represented by the formula (b2b) in the first-b block is preferably 0.90 or less, more preferably 0.30 or less, and further preferably 0.01 or more and 0.10 or less in terms of easily obtaining the effect of the present invention.

In the first block copolymer, a proportion of the number of moles of the constituent unit of the first-a block to a sum of the number of moles of the constituent unit of the first-a block and the number of moles of the constituent unit first-b block is preferably 20 mol % or more and 80 mol % or less. The proportion of the number of moles of the constituent unit of the first-a block is more preferably 30 mol % or more, and further preferably 35 mol % or more. The proportion of the number of moles of the constituent unit of the first-a block is more preferably 75 mol % or less, and further preferably 70 mol % or less.

The first block copolymer may have another block in addition to the first-a block and the first-b block. In a preferable aspect, the first block copolymer is a diblock copolymer constituted by the first-a block and the first-b block.

A number-average molecular weight (Mn) of the first block copolymer is not particularly limited, but preferably 3,000 or more and 100,000 or less, more preferably 6,000 or more and 70,000 or less, further preferably 8,000 or more and 50,000 or less, and particularly preferably 10,000 or more and 40,000 or less. A degree of dispersion of molecular weight (Mw/Mn) of each block constituting the block copolymer is preferably 1.0 or more and 1.5 or less, more preferably 1.0 or more and 1.4 or less, and further preferably 1.0 or more and 1.3 or less. [Method for Producing First Block Copolymer]

The first block copolymer may be produced by a known method, and for example, the first block copolymer may be produced by the same producing method as the producing method described in Japanese Unexamined Patent Application, Publication No. 2022-20519.

### <Second Block Copolymer>

The second block copolymer has a second-a block and a second-b block, the second-a block is constituted by the polymer having the repeating structure of the constituent unit represented by the formula (b1), and the second-b block is constituted by the polymer having the repeating structure of the constituent unit represented by the formula (b2b). The second block copolymer has a number-average molecular weight of 40000 or less in terms of standard polystyrene as determined by gel permeation chromatography (GPC) measurement.

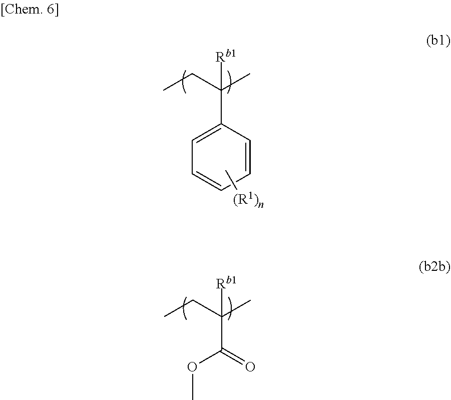

(In the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality of R¹ may be the same as or different from each other, and
in the formula (b2b), R^{b2} is each independently a hydrogen atom, an alkyl group having 1 or more and 5 or less carbon atoms, or a halogenated alkyl group having 1 or more and 5 or less carbon atoms, and a plurality of R^{b2} may be the same as or different from each other.)

In the second-a block, a preferable aspect of the constituent unit represented by the formula (b1) is the same as the constituent unit represented by the formula (b1) in the first-a block.

In the second-a block, n in the formula (b1) is preferably 0. This more hardly induces the phase separation when using the second block copolymer, which more easily yields the effect of the present invention.

In the second-b block, a preferable aspect of the constituent unit represented by the formula (b2b) is the same as the constituent unit represented by the formula (b2b) in the first-b block.

In the second block copolymer, a proportion of the number of moles of the constituent unit of the second-a block to a sum of the number of moles of the constituent unit of the second-a block and the number of moles of the constituent unit second-b block is preferably 20 mol % or more and 80 mol % or less. The proportion of the number of moles of the constituent unit of the second-a block is more preferably 30 mol % or more, and further preferably 35 mol % or more. The proportion of the number of moles of the constituent unit of the second-a block is more preferably 75 mol % or less, and further preferably 70 mol % or less.

The second block copolymer may have another block in addition to the second-a block and the second-b block. In a preferable aspect, the second block copolymer is a diblock copolymer constituted by the second-a block and the second-b block.

A number-average molecular weight (Mn) of the second block copolymer is 40,000 or less, preferably 3,000 or more and 40,000 or less, more preferably 6,000 or more and 40,000 or less, further preferably 8,000 or more and 35,000 or less, and particularly preferably 10,000 or more and 35,000 or less. A degree of dispersion of molecular weight (Mw/Mn) of each block constituting the block copolymer is preferably 1.0 or more and 1.5 or less, more preferably 1.0 or more and 1.4 or less, and further preferably 1.0 or more and 1.3 or less.

A proportion of a mass of the first block copolymer to a sum of the mass of the first block copolymer and a mass of the second block copolymer is preferably 30 mass % or more and 95 mass % or less, more preferably 40 mass % or more and 85 mass % or less, further preferably 40 mass % or more and 70 mass % or less, and particularly preferably 40 mass % or more and 60 mass % or less. The ratio within the above numerical range more easily yields the effect of the present invention.

### <Organic Solvent Component>

The resin composition for forming a phase-separated structure preferably contains an organic solvent. The organic solvent component may be any organic solvent that can dissolve each of the used components to form a uniform solution. A given organic solvent selected from organic solvents conventionally known as a solvent of a composition containing a resin as a main component may be used.

Examples of the organic solvent component include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; polyhydric alcohol monoacetates such as ethylene glycol monoacetate, diethylene glycol monoacetate, propylene glycol monoacetate, or dipropylene glycol monoacetate; derivatives of the polyhydric alcohol such as a compound having an ether bond such as a monoalkyl ether or a monophenyl ether such as a monomethyl ether, a monoethyl ether, a monopropyl ether, a monobutyl ether, etc. of the polyhydric alcohols or the polyhydric alcohol monoacetates [among these, propylene glycol monomethyl ether acetate (PGMEA) or propylene glycol monomethyl ether (PGME) is preferable]; cyclic ethers such as dioxane; esters other than the polyhydric alcohol monoacetates and the derivative of the polyhydric alcohols described above, such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, and mesitylene. The organic solvent component may be used alone, or two or more may be used as a mixed solvent. Among these, propylene glycol monomethyl ether acetate (PGMEA), propylene glycol monomethyl ether (PGME), cyclohexanone, and ethyl lactate (EL) are preferable.

The organic solvent component contained in the resin composition for forming a phase-separated structure is not particularly limited. The organic solvent component is appropriately set according to the coating film thickness such that the resin composition for forming a phase-separated structure has a concentration with which the composition can be applied. The organic solvent component is typically used such that the solid-content concentration of the resin composition for forming a phase-separated structure is in a range of between 0.2 mass % or more and 70 mass % or less, preferably between 0.2 mass % or more and 50 mass % or less.

### <Optional Component>

The resin composition for forming a phase-separated structure may contain an optional component in addition to the aforementioned block copolymer and the organic solvent component. Examples of the optional component include another resin, a surfactant, a dissolution inhibiting agent, a plasticizing agent, a stabilizing agent, a coloring agent, an anti-halation agent, a dye, a sensitizing agent, a base proliferating agent, and a basic compound.

<<Method for Producing Structure having Phase-Separated Structure>>

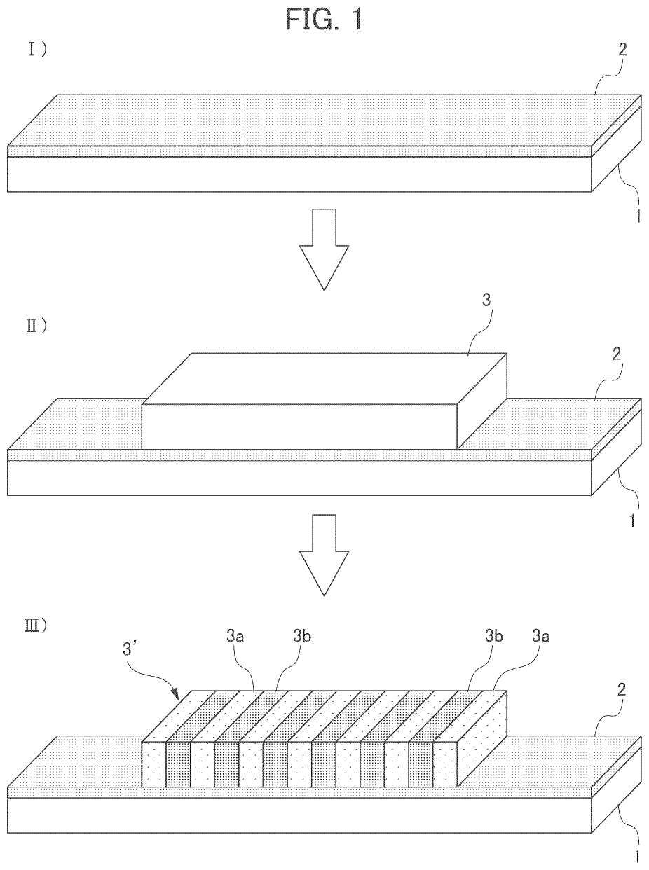

A method for producing a structure having a phase-separated structure includes: applying the resin composition for forming a phase-separated structure on a support to form a layer containing a block copolymer (hereinafter, referred to as “step (i)”); and phase separating the layer containing the block copolymer (hereinafter, referred to as “step (ii)”). Hereinafter, this method for producing a structure having a phase-separated structure will be specifically described with reference to FIG. 1. Note that the method for producing a structure having a phase-separated structure is not limited to the aspect specifically illustrated in FIG. 1.

FIG. 1 illustrates an exemplary embodiment of the method for producing a structure having a phase-separated structure. In the embodiment illustrated in FIG. 1, an undercoat agent is firstly applied on a support 1 to form an undercoat agent layer 2 (FIG. 1 (I)). Next, the resin composition for forming a phase-separated structure is applied on the undercoat agent layer 2 to form a layer (BCP layer) 3 containing the block copolymer (FIG. 1 (II); the above is the step (i)). Next, the BCP layer 3 is annealed by heating to phase-separate the BCP layer 3 into a phase 3a and a phase 3b (FIG. 1 (III); the step (ii)). According to this producing method of the embodiment, namely the producing method including the step (i) and the step (ii), a structure 3′ having a phase-separated structure is produced on the support 1 on which the undercoat agent layer 2 is formed.

<Step (i)>

In the step (i), the resin composition for forming a phase-separated structure is applied on the support 1 to form the BCP layer 3. In the embodiment illustrated in FIG. 1, the undercoat agent is firstly applied on the support 1 to form the undercoat agent layer 2. Providing the undercoat agent layer 2 on the support 1 can achieve hydrophilic-hydrophobic balance between the support 1 surface and the layer (BCP layer) 3 containing the block copolymer. That is, the undercoat agent layer 2 containing the resin component having the constituent unit constituting the first-a block increases adhesiveness between the phase composed of the first-a block in the BCP layer 3 and the support 1. The undercoat agent layer 2 containing the resin component having the constituent unit constituting the first-b block increases adhesiveness between the phase composed of the first-b block in the BCP layer 3 and the support 1. According to this, the phase separation of the BCP layer 3 easily forms the phase-separated structure oriented in the direction perpendicular to the support 1 surface.

### Undercoat Agent:

As the undercoat agent, a resin composition may be used. The resin composition for the undercoat agent may be appropriately selected from among conventionally known resin compositions used for forming a thin film according to the type of the blocks constituting the block copolymer. The resin composition for the undercoat agent may be, for example, a thermally polymerizable resin composition or may be a photosensitive resin composition such as a positive-type resist composition or a negative-type resist composition. Furthermore, a non-polymerizable film formed by applying a compound serving as a surface-treating agent may also be used as the undercoat agent layer. For example, a siloxane-based organic monomolecular film formed by applying phenethyltrichlorosilane, octadecyltrichlorosilane, hexamethyldisilazane, etc., as the surface-treating agent can also be suitably used as the undercoat agent layer.

Examples of the resin composition as above include: a resin composition containing a resin having both the constituent units respectively constituting the first-a block and the first-b block; and a resin composition containing a resin having both constituent units having high compatibility with the blocks constituting the block copolymer. As the resin composition for the undercoat agent, preferably used are: a composition containing a resin having both styrene and methyl methacrylate as constituent units; and a compound or composition having a moiety having high compatibility with styrene, such as an aromatic ring, and a moiety having high compatibility with methyl methacrylate (such as a highly polar functional group). Examples of the resin having both styrene and methyl methacrylate as constituent units include a random copolymer of styrene and methyl methacrylate, and an alternate polymer of styrene and methyl methacrylate (polymer in which each polymer is alternately copolymerized). Examples of the composition having both of a moiety having high compatibility with styrene and a moiety having high compatibility with methyl methacrylate include a composition containing a resin obtained by polymerizing at least a monomer having an aromatic ring and a monomer having a highly polar functional group. Examples of the monomer having an aromatic ring include a monomer having an aryl group in which one hydrogen atom is removed from an aromatic hydrocarbon ring, such as a phenyl group, a biphenyl group, a fluorenyl group, a naphthyl group, an anthryl group, or a phenanthryl group, or a heteroaryl group in which a portion of carbon atoms constituting a ring on the aforementioned groups is substituted with a heteroatom such as an oxygen atom, a sulfur atom, or a nitrogen atom. Furthermore, examples of the monomer having a highly polar functional group include: a monomer having a trimethoxysilyl group, a trichlorosilyl group, an epoxy group, a glycidyl group, a carboxy group, a hydroxy group, a cyano group, or a hydroxyalkyl group in which a portion of hydrogen atoms in an alkyl group is substituted with a hydroxy group. Other examples of the compound having both a moiety having high compatibility with styrene and a moiety having high compatibility with methyl methacrylate include: a compound having both an aryl group and a highly polar functional group, such as phenethyltrichlorosilane; and a compound having both an alkyl group and a highly polar functional group, such as an alkylsilane compound.

The resin composition for the undercoat agent can be produced by dissolving the aforementioned resin in a solvent. Such a solvent may be any solvent that can dissolve each component to be used and form a homogeneous solution. Examples thereof include the same solvents as the organic solvent components exemplified in the description for the resin composition for forming a phase-separated structure.

The type of the support 1 is not particularly limited as long as the resin composition can be applied on the surface. Examples thereof include: a substrate composed of an inorganic material such as silicon, a metal (such as copper, chromium, iron, and aluminum), glass, titanium oxide, silica, and mica; a substrate composed of an oxide such as SiO₂; a substrate composed of a nitride such as SiN; a substrate composed of an oxynitride such as SiON; and a substrate composed of an organic material such as acryl resin, polystyrene, cellulose, cellulose acetate, or a phenolic resin. Among these, a silicon substrate (Si substrate) or a metal substrate is suitable, a Si substrate or a copper substrate (Cu substrate) is more suitable, and a Si substrate is particularly suitable. The size and shape of the support 1 are not particularly limited. The support 1 does not necessarily have a smooth surface, and substrates having various shapes can be appropriately selected. Examples thereof include a substrate having a curved surface, a flat plate having an uneven surface, or a flaky substrate may be used.

An inorganic and/or organic film may be provided on the surface of the support 1. An example of the inorganic film is an inorganic antireflection film (inorganic BARC). An example of the organic film is an organic antireflection film (organic BARC). The inorganic film can be formed by, for example, applying an inorganic antireflection film composition such as a silicon-based material on the support, and baking the resultant. The organic film can be formed by, for example, applying a material for forming an organic film in which a resin component etc. to constitute the film is dissolved in an organic solvent on the substrate with a spinner etc., and performing a baking treatment under a heating condition of preferably 200° C. or higher and 300° C. or lower for preferably 30 seconds or more and 300 seconds or less, and more preferably for 60 seconds or more and 180 seconds or less. This material for forming an organic film does not necessarily require sensitivity to light or electron beam, such as a resist film, and may or may not have such sensitivity. Specifically, a resist or a resin commonly used for producing semiconductor elements or liquid crystal display elements may be used. Furthermore, the material for forming an organic film is preferably a material capable of forming an organic film that can be subjected to etching, particularly dry-etching, so that a pattern formed by processing the BCP layer 3 and composed of the block copolymer can be transferred to the organic film by etching the organic film using the pattern to form the organic film pattern. Among these, a material capable of forming an organic film that can be subjected to etching such as oxygen plasma etching is preferable. Such a material for forming an organic film may be a material conventionally used for forming an organic film such as organic BARC. Examples thereof include: the ARC series, manufactured by Nissan Chemical Corporation; the AR series, manufactured by Rohm and Haas Japan Ltd.; and the SWK series, manufactured by TOKYO OHKA KOGYO CO., LTD.

A method for forming the undercoat agent layer 2 by applying the undercoat agent on the support 1 is not particularly limited, and conventionally known methods may be used to form the undercoat agent layer 2. For example, the undercoat agent is applied on the support 1 by a conventionally known method such as spin coating or by using a spinner to form a coating film, which is then dried to form the undercoat agent layer 2. A method for drying the coating film may be any as long as a solvent included in the undercoat agent can be volatilized, and an example thereof includes a method of baking. In this case, the baking temperature is preferably 80° C. or higher and 300° C. or lower, more preferably 180° C. or higher and 270° C. or lower, and further preferably 220° C. or higher and 250° C. or lower. The baking time is preferably 30 seconds or more and 600 seconds or less, and more preferably 60 seconds or more and 600 seconds or less. A thickness of the undercoat agent layer 2 after drying the coating film is preferably about 10 nm or more and 100 nm or less, and more preferably about 40 nm or more and 90 nm or less.

The surface of the support 1 may be cleaned in advance before forming the undercoat agent layer 2 on the substrate 1. Cleaning the surface of the support 1 improves coatability of the undercoat agent. A conventionally known cleaning treatment method may be used, and examples thereof include an oxygen plasma treatment, an ozone oxidation treatment, an acid alkali treatment, and a chemical modification treatment.

After the undercoat agent layer 2 is formed, the undercoat agent layer 2 may be rinsed by using a rinsing liquid such as a solvent, as necessary. Since the rinsing removes uncrosslinked portions etc. in the undercoat agent layer 2, compatibility with at least one block constituting the block copolymer is improved, and thus, the phase-separated structure composed of a cylinder structure oriented in the direction perpendicular to the surface of the support 1 is to be easily formed. The rinsing solution may be any liquid that can dissolve the uncrosslinked portions. Solvents such as propylene glycol monomethyl ether acetate (PGMEA), propylene glycol monomethyl ether (PGME), and ethyl lactate (EL), or commercially available thinner solutions can be used. After the cleaning, post-baking may be performed to volatilize the rinsing solution. A temperature condition during this post-baking is preferably 80° C. or higher and 300° C. or lower, and more preferably 100° C. or higher and 270° C. or lower. The baking time is preferably 30 seconds or more and 500 seconds or less, and more preferably 60 seconds or more and 240 seconds or less. The thickness of the undercoat agent layer 2 after this post-baking is preferably about 1 nm or more and 10 nm or less, and more preferably about 2 nm or more and 7 nm or less.

Next, the layer (BCP layer) 3 containing the block copolymer is formed on the undercoat agent layer 2. A method for forming the BCP layer 3 on the undercoat agent layer 2 is not particularly limited, and examples thereof include a method in which the resin composition for forming a phase-separated structure of the aforementioned embodiment is applied on the undercoat agent layer 2 by a conventionally known method such as spin coating or by using a spinner to form a coating film, and then drying the coating film.

A thickness of the BCP layer 3 may be any as long as the thickness is sufficient for inducing the phase separation, and is preferably 10 nm or more and 100 nm or less, and more preferably 20 nm or more and 80 nm or less with consideration of the type of the support 1 or the structural period size, uniformity of the nano-structure, etc. of the phase separated structure to be formed. For example, when the support 1 is a Si substrate, the thickness of the BCP layer 3 is regulated to be preferably 10 nm or more and 100 nm or less, and more preferably 20 nm or more and 80 nm or less.

<Step (ii)>

In the step (ii), the BCP layer 3 formed on the support 1 is phase-separated. The support 1 after the step (i) is subjected to an annealing treatment by heating and the block copolymer is selectively removed to form a phase-separated structure such that at least a portion of the support 1 surface is exposed. That is, a structure 3′ having a phase-separated structure that is phase-separated into the phase 3a and the phase 3b is produced on the support 1. The temperature condition during the annealing treatment is preferably a temperature higher than or equal to the glass transition temperature of the used block copolymer and lower than the pyrolysis temperature of the used block copolymer. For example, when the block copolymer is a polystyrene-polymethyl methacrylate (PS-PMMA) block copolymer (weight average molecular weight: 5000 or more and 100000 or less), the temperature condition is preferably 180° C. or higher and 270° C. or lower. The heating time is preferably 30 seconds or more and 3600 seconds or less. The annealing treatment is preferably performed in a less reactive gas such as nitrogen.

### <Optional Step>

The method for producing a structure having a phase-separated structure is not limited to the aforementioned embodiment, and may include a step (optional step) other than the steps (i) and (ii).

Examples of the optional step include a step of selectively removing a phase composed of at least one block of the first block and the second block constituting the block copolymer in the BCP layer 3 (hereinafter referred to as “step (iii)”), and a guide pattern formation step.

Step (iii)

In the step (iii), a phase composed of at least one block of the first block and the second block constituting the block copolymer is selectively removed from the BCP layer, which is formed on the undercoat agent layer 2. This results in formation of a fine pattern (polymer nanostructure).

Examples of the method for selectively removing the phase composed of the block include: a method for subjecting the BCP layer to an oxygen plasma treatment; and a method for subjecting the BCP layer to a hydrogen plasma treatment. For example, the BCP layer containing the block copolymer is phase-separated, and then the BCP layer is subjected to the oxygen plasma treatment, the hydrogen plasma treatment, etc. to selectively not remove the phase composed of the first-a block (b1) and to selectively remove the phase composed of the first-b block (b2).

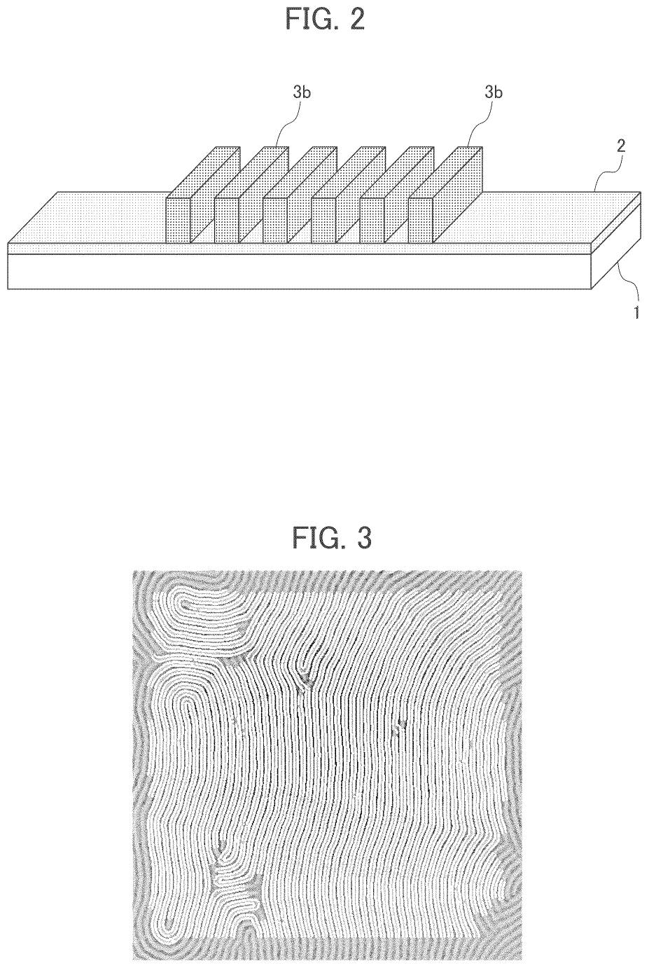

FIG. 2 illustrates an exemplary embodiment of the step (iii). In the embodiment illustrated in FIG. 2, the phase 3a is selectively removed by subjecting the structure 3′ produced on the support 1 in the step (ii) to the oxygen plasma treatment to form a separated pattern (polymer nanostructure) composed of separated phases 3b. In this case, the phase 3b is the phase composed of the first block, and phase 3a is the phase composed of the second block.

The support 1 with the pattern formed by the phase separation of the BCP layer 3 composed of the block copolymer as described above can be used as is, or the shape of the pattern (polymer nanostructure) on the support 1 can be changed by further heating. The temperature condition during the heating is preferably a temperature higher than or equal to a glass transition temperature of the used block copolymer and lower than the pyrolysis temperature of the used block copolymer. The heating is preferably performed in a less reactive gas such as nitrogen.

### Guide Pattern Formation Step

The method for producing a structure having a phase-separated structure may also include a step of providing a guide pattern on the undercoat agent layer (guide pattern formation step) between the aforementioned step (i) and step (ii). This can control the array structure of the phase-separated structure. For example, even for block copolymers that form a random fingerprint-like phase-separated structure without guide pattern, a groove structure of a resist film can be provided on the surface of the undercoat agent layer to obtain a phase-separated structure oriented along the groove. According to the principle as above, the guide pattern may be provided on the undercoat agent layer 2. The compatibility of the surface of the guide pattern to any of the blocks constituting the above block copolymer facilitates the formation of a phase-separated structure composed of a cylinder structure and oriented in the direction perpendicular to the support surface.

The guide pattern can be formed by, for example, using a resist composition. For the resist composition forming the guide pattern, a resist composition having compatibility with any of the blocks constituting the above block copolymers can be appropriately selected for use from among resist compositions commonly used for forming resist patterns or their modifications. The resist composition may be either of: a positive-type resist composition to form a positive-type pattern, namely an exposed area of a resist film is dissolved and removed; or a negative-type resist composition to form a negative-type pattern, namely an unexposed area of a resist film is dissolved and removed, but a negative-type resist composition is preferable. The negative-type resist composition is preferably a resist composition containing, for example, an acid generator and a base material component having a solubility in an organic solvent-containing developing solution that decreases under action of an acid, the base material component containing a resin component having a constituent unit degraded under action of an acid to have increased polarity. After the BCP composition is poured onto the undercoat agent layer with the formed guide pattern, an annealing treatment is performed to induce the phase separation. Thus, a composition capable of forming a resist film while having excellent solvent resistance and heat resistance is preferable as the resist composition for forming the guide pattern.

### EXAMPLES

The present invention will now be described in more detail based on Examples, but the invention is not limited to these examples.

Hereinafter, block copolymers used in Examples and Comparative Examples will be described. BCP (1-1) to BCP (1-3) were prepared with reference to Examples of Japanese Unexamined Patent Application, Publication No. 2022-20519. BCP (1-4) to BCP (1-6) and BCP (1-0) were prepared with reference to Examples of Japanese Unexamined Patent Application, Publication No. 2022-20519, and 1-propanethiol, 1-octanethiol, or thioacetic acid was respectively used instead of 2,2,2-trifluoroethanethiol.
BCP (1-1) to BCP (1-3): Block copolymer of: block composed of polystyrene; and block composed of random copolymer of 2-hydroxy-3-(2,2,2-trifluoroethylsulfanyl) propyl methacrylate and methyl methacrylate
BCP (1-4) and BCP (1-10): Block copolymer of: block composed of polystyrene; and block composed of random copolymer of 2-hydroxy-3-(propylsulfanyl) propyl methacrylate and methyl methacrylate
BCP (1-5): Block copolymer of: block composed of polystyrene; and block composed of random copolymer of 2-hydroxy-3-(octylsulfanyl) propyl methacrylate and methyl methacrylate
BCP (1-6): Block copolymer of: block composed of polystyrene; and block composed of random copolymer of 2-hydroxy-3-(acetylsulfanyl) propyl methacrylate and methyl methacrylate
BCP (1-7) and BCP (1-11): Block copolymer of: block composed of polystyrene; and block composed of random copolymer of 2-methoxyethyl methacrylate and methyl methacrylate
BCP (1-8) and BCP (1-12): Block copolymer of: block composed of polystyrene; and block composed of random copolymer of 2-hydroxyethyl methacrylate and methyl methacrylate
BCP (1-9) and BCP (1-13): Block copolymer of: block composed of poly(4-ethylstyrene); and block composed of polymethyl methacrylate
BCP (2-1) to BCP (2-6): Block copolymer of: block composed of polystyrene; and block composed of polymethyl methacrylate
   <Measurement of Mole Ratio between Constituent Units of Blocks>

By ¹H-NMR measurement (600 MHZ, deuterated acetone) using an NMR apparatus (manufactured by Bruker, equipped with CryoProbe), a value of integration ratio (area ratio) was measured from chemical shifts of the constituent unit of the block copolymers to calculate a mole ratio between constituent units of the blocks.

Table 1 and Table 2 summarize: the number-average molecular weight (Mn) of the block copolymers; the degree of dispersion of molecular weight (PDI=Mw/Mn); a ratio (x:y:z) between the number of moles of the constituent unit (b1), the number of moles of the constituent unit (b2a), and the number of moles of the constituent unit (b2b) to a sum of numbers of moles of the constituent units; a ratio (y/(y+z)) of the number of moles of the constituent unit (b2a) to a sum of the number of moles of the constituent unit (b2a) and the number of moles of the constituent unit (b2b); and L₀.

TABLE 1

| | Mn | PDI | x:y:z | y/(y + z) | L₀ (nm) |
|---|---|---|---|---|---|
| BCP (1-1) | 22,300 | 1.06 | 49.9:7.0:43.1 | 0.14 | 18.6 |
| BCP (1-2) | 16,800 | 1.05 | 48.5:6.4:45.1 | 0.12 | 15.2 |
| BCP (1-3) | 31,500 | 1.06 | 54.1:1.5:44.4 | 0.03 | 22.7 |
| BCP (1-4) | 20,400 | 1.03 | 48.4:4.4:47.2 | 0.09 | 16.4 |
| BCP (1-5) | 28,500 | 1.04 | 50.8:4.6:44.6 | 0.09 | 21.1 |
| BCP (1-6) | 25,700 | 1.05 | 45.5:4.8:49.7 | 0.09 | 19.8 |
| BCP (1-7) | 26,500 | 1.07 | 47.3:4.5:48.2 | 0.09 | 20.2 |
| BCP (1-8) | 25,500 | 1.10 | 49.1:3.3:47.6 | 0.06 | 19.9 |
| BCP (1-9) | 27,100 | 1.09 | 49.9:0:50.1 | — | 22.2 |
| BCP (1-10) | 34,500 | 1.04 | 64.8:1.3:33.9 | 0.04 | 24.6 |
| BCP (1-11) | 32,700 | 1.05 | 64.0:1.5:34.5 | 0.04 | 23.5 |
| BCP (1-12) | 31,100 | 1.21 | 67.4:1.8:30.8 | 0.06 | 23.3 |
| BCP (1-13) | 28,800 | 1.11 | 65.0:0:35.0 | — | 20.0 |

TABLE 2

| | Mn | PDI | x:y:z |
|---|---|---|---|
| BCP (2-1) | 18,800 | 1.05 | 49.5:0:50.5 |
| BCP (2-2) | 21,500 | 1.05 | 50.1:0:49.9 |
| BCP (2-3) | 25,500 | 1.04 | 48.1:0:51.9 |
| BCP (2-4) | 30,400 | 1.04 | 51.1:0:48.9 |
| BCP (2-5) | 30,500 | 1.02 | 67.9:0:32.1 |
| BCP (2-6) | 34,500 | 1.03 | 64.5:0:35.5 |

### <Preparation of Resin Composition for Forming Phase-Separated Structure and Production of Structure Having Phase-Separated Structure>

Each of BCP shown in Tables 3 and 4 and propylene glycol monomethyl ether were mixed and dissolved to prepare each of resin compositions for forming a phase-separated structure of Examples (solid-content concentration: 1.0 mass %).

On a 12-inch silicon wafer, a neutralized film composition solution (undercoat agent) prepared as a PGMEA solution at a concentration of 2 wt % was applied by using a spinner at 1500 rpm, and baked and dried under a nitrogen atmosphere at 250° C. for 300 seconds to form a layer (undercoat agent layer) composed of a neutralized film with 60 nm in film thickness on the substrate. Subsequently, a portion in the neutralized film other than the substrate adhesion portion was removed with OK73 thinner (trade name, manufactured by TOKYO OHKA KOGYO CO., LTD.), post-baked at 100° C. for 60 seconds, the resin composition for forming a phase-separated structure of each of Examples was applied on the layer composed of the neutralized film by spin-coating, and then soft-baked at 90° C. for 60 seconds to form a BCP layer with 25 nm in film thickness. Used as the neutralized film composition solution was a propylene glycol monomethyl ether acetate solution of a copolymer having a styrene (St) unit, a methyl methacrylate (MMA) unit, and a 2-hydroxyethyl methacrylate (HEMA) unit (St/MMA/HEMA=82/12/6 (mol %), number-average molecular weight: 25,700, weight-average molecular weight (Mw): 45,300, dispersion degree (PDI): 1.76).

The formed resin composition layer was annealed under a nitrogen atmosphere to form a phase-separated structure. A temperature and a time for the annealing were 220° C. for 5 minutes in Examples 1 to 11 and Comparative Example 1 (lamella structure), or 200° C. for 15 minutes in Examples 12 to 16 and Comparative Example 2 (cylinder structure).

Thereafter, in Examples 12 to 16 and Comparative Example 2, the substrate with the formed phase-separated structure was irradiated with ultraviolet ray (A: 172 nm, 160 mJ) under a nitrogen atmosphere by using CLEAN TRACK LITHIUS Pro-Z (manufactured by Tokyo Electron Ltd.). Thereafter, development was performed with isopropyl alcohol to selectively remove the phase composed of polymethyl methacrylate, resulting in formation of a hole pattern.

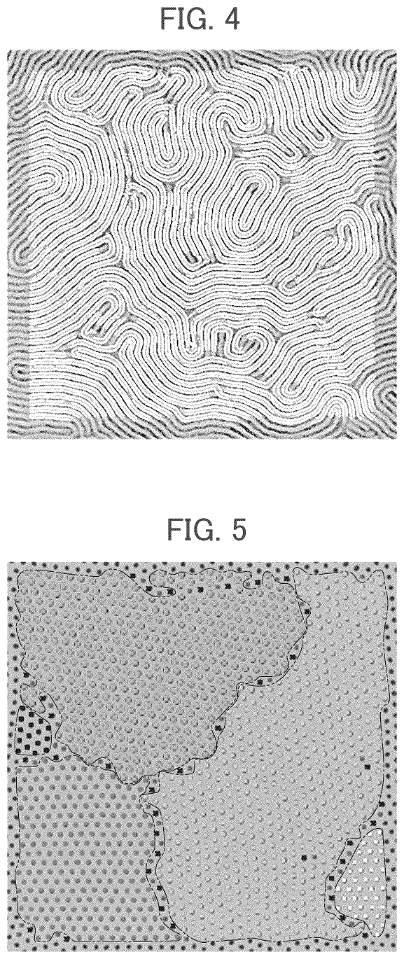

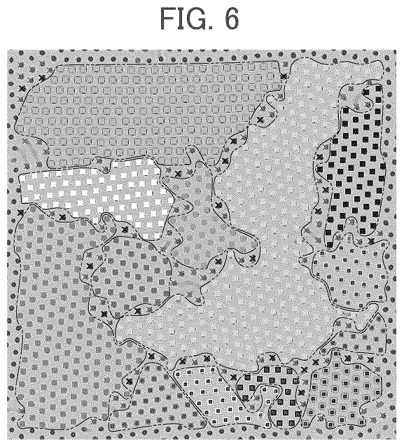

The following evaluations were performed. Table 3 shows the results of Examples 1 to 11 and Comparative Example 1, and Table 4 shows the results of Examples 12 to 16 and Comparative Example 2. The image in Example 3 is shown in FIG. 3, the image in Comparative Example 1 is shown in FIG. 4, the image in Example 12 is shown in FIG. 5, and the image in Comparative Example 2 is shown in FIG. 6.

### (Evaluation of Fingerprint Edge Roughness (FER))

With 100 images of the surface (phase-separated state) of the substrate obtained in Examples 1 to 11 and Comparative Example 1, 30, which was an index indicating FER, was determined. This is shown in Table 3 as “FER (nm)”. The “30” was measured by a method from a fingerprint pattern of the surface (phase-separated state) of the obtained substrate observed with a length-measuring SEM (scanning electron microscope, trade name: CG6300, manufactured by Hitachi High-Tech Corporation, acceleration voltage: 800 eV, current value: 15 pA, Frame256, magnification: 100k (image in 1350-nm square)) using an off-line length-measuring software (manufactured by Hitachi High-Tech Corporation). The 30 refers to a triple value (30) (unit: nm) of a standard deviation (o) determined from the measurement result. A smaller value of the 30 means that a structure having a good shape and more reduced roughness with smaller roughness of the structure having the phase-separated structure can be obtained.

### (Evaluation of Grain Number)

Each of the hole pattern formed in Examples 12 to 16 and Comparative Example 2 was subjected to image analysis by using the above off-line length-measuring software to determine a Grain number from an image in 1350-nm square. This is shown in Table 4 as “Grain (number)”. A smaller Grain number means that hole patterns with the same pitch and the same shape are more continuously formed, namely means increase in the process margin and reduction in defect.

### (Annealing Temperature)

In the production of the structure having the phase-separated structure, the temperature of the annealing was changed by 10° C. to determine a highest temperature among temperatures for the normal orientation. Table 3 and Table 4 show the results. Note that the normal orientation means that, in the SEM image of the substrate after the annealing, a proportion of the fingerprint structure without defect is 80% or more in Examples 1 to 11 and Comparative Example 1, and a proportion of the perpendicular random hole structure is 80% or more in Examples 12 to 16 and Comparative Example 2.

TABLE 3

| | | | Mixing ratio | | | Annealing |
|---|---|---|---|---|---|---|
| | BCP | | (mass %) | | FER | Temperature |
| | First | Second | First | Second | (nm) | (° C.) |
| Example 1 | 1-1 | 2-2 | 75 | 25 | 4.38 | 230 |
| Example 2 | 1-1 | 2-2 | 50 | 50 | 3.92 | 240 |
| Example 3 | 1-2 | 2-1 | 50 | 50 | 3.35 | 230 |
| Example 4 | 1-3 | 2-4 | 80 | 20 | 4.91 | 250 |
| Example 5 | 1-4 | 2-2 | 75 | 25 | 3.45 | 240 |
| Example 6 | 1-4 | 2-2 | 50 | 50 | 3.15 | 250 |
| Example 7 | 1-5 | 2-4 | 50 | 50 | 4.52 | 230 |
| Example 8 | 1-6 | 2-3 | 50 | 50 | 5.11 | 230 |
| Example 9 | 1-7 | 2-3 | 50 | 50 | 6.45 | 230 |
| Example 10 | 1-8 | 2-3 | 50 | 50 | 7.73 | 230 |
| Example 11 | 1-9 | 2-3 | 50 | 50 | 8.51 | 230 |
| Comparative | 1-1 | — | 100 | 0 | 13.76 | 220 |
| Example 1 | | | | | | |

TABLE 4

| | | | Mixing ratio | | | Annealing |
|---|---|---|---|---|---|---|
| | BCP | | (mass %) | | Grain | temperature |
| | First | Second | First | Second | (number) | (° C.) |
| Example 12 | 1-10 | 2-6 | 50 | 50 | 7 | 240 |
| Example 13 | 1-10 | 2-6 | 75 | 25 | 10 | 230 |
| Example 14 | 1-11 | 2-5 | 50 | 50 | 9 | 250 |
| Example 15 | 1-12 | 2-5 | 50 | 50 | 7 | 260 |
| Example 16 | 1-13 | 2-5 | 50 | 50 | 12 | 240 |
| Comparative | 1-10 | — | 100 | 0 | 21 | 200 |
| Example 2 | | | | | | |

As shown in Tables 3 and 4, it has been confirmed that the phase-separated structure with low FER can be formed in Examples 1 to 11. It has been also confirmed that the phase-separated structure with a low Grain number can be formed in Examples 12 to 16. Therefore, it is understood that the resin compositions for forming a phase-separated structure used in Examples 1 to 16 can form the phase-separated structure having reduced pattern roughness or pattern error. Further, it has been confirmed that these Examples yield the normal orientation even at raised annealing temperature.

What is claimed is:

1. A resin composition for forming a phase-separated structure, the resin composition comprising a first block copolymer and a second block copolymer, wherein:
the first block copolymer has a first-a block and a first-b block;
the second block copolymer has a second-a block and a second-b block;
the first-a block and the second-a block are each independently comprise a polymer having a repeating structure of a constituent unit represented by formula (b1);
the second-b block is constituted by a polymer having a repeating structure of a constituent unit represented by formula (b2b);
the second block copolymer has a number-average molecular weight of 40,000 or less in terms of standard polystyrene as determined by gel permeation chromatography (GPC) measurement; and
the first block copolymer satisfies any one of (1) or (2) below:
(1) the first-b block comprises a random copolymer having a structure in which a constituent unit represented by formula (b2a) and the constituent unit represented by formula (b2b) are randomly arranged,
(2) in the first-a block, n in formula (b1) is an integer between 1 and 5 inclusive, and
the first-b block comprises a polymer having a repeating structure of the constituent unit represented by formula (b2b): 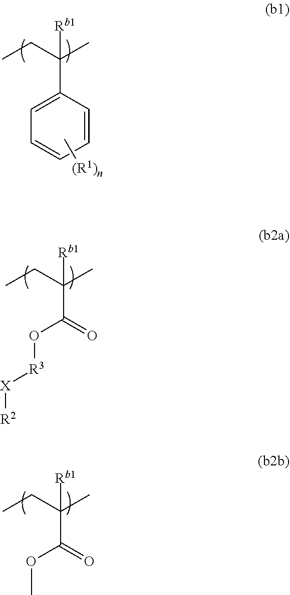
wherein, in the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality of R¹ may be same as or different from each other,
in the formula (b2a), X is a sulfur atom or an oxygen atom, R³ is an alkylene group optionally having a hydroxy group, and R² is a hydrogen atom or a monovalent organic group, and
in the formula (b2a) and the formula (b2b), R^{b2} is each independently a hydrogen atom, an alkyl group having 1 or more and 5 or less carbon atoms, or a halogenated alkyl group having 1 or more and 5 or less carbon atoms, and a plurality of R^{b2} may be same as or different from each other.

2. The resin composition for forming a phase-separated structure according claim 1, wherein R² in the formula (b2a) is a hydrogen atom, an acyl group, a thioacyl group, an alkenyl group, or an alkyl group optionally having a silyl group, a fluorine atom, a carboxy group, an amino group, a hydroxy group, or a phosphoric acid group.

3. The resin composition for forming a phase-separated structure according to claim 1, wherein a proportion of a mass of the first block copolymer to a sum of the mass of the first block copolymer and a mass of the second block copolymer is 30 mass % or more and 95 mass % or less.

4. The resin composition for forming a phase-separated structure according to claim 1, wherein
a proportion of a number of moles of a constituent unit of the first-a block to a sum of the number of moles of the constituent unit of the first-a block and a number of moles of the constituent unit of the first-b block is 20 mol % or more and 80 mol % or less, and
a proportion of a number of moles of a constituent unit of the second-a block to a sum of the number of moles of the constituent unit of the second-a block and a number of moles of the constituent unit of the second-b block is 20 mol % or more and 80 mol % or less.

5. The resin composition for forming a phase-separated structure according to claim 1, wherein, when the first block copolymer satisfies (1), a ratio of a number of moles of the constituent unit represented by the formula (b2a) to a sum of the number of moles of the constituent unit represented by the formula (b2a) and a number of moles of the constituent unit represented by the formula (b2b) in the first-b block is 0.90 or less.

6. A method for producing a structure having a phase-separated structure, the method comprising:
applying the resin composition for forming a phase-separated structure according to claim 1 on a support to form a layer containing a block copolymer; and
phase separating the layer containing the block copolymer.
